(19) United States
(12) Patent Application Publication
(10) Pub. No.: US 2008/0251802 A1
(43) Pub. Date: Oct. 16, 2008

(54) METHOD FOR DEPOSITION OF (Al,In,Ga,B)N

(75) Inventors: Michael Iza, Santa Barbara, CA (US); Steven P. DenBaars, Goleta, CA (US); Shuji Nakamura, Santa Barbara, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 12/102,612

(22) Filed: Apr. 14, 2008

Related U.S. Application Data
(60) Provisional application No. 60/911,323, filed on Apr. 12, 2007.

(51) Int. Cl. H01L 33/00; H01L 21/00

(52) U.S. Cl. 257/94; 438/47; 257/E21.001; 257/E33.001

(57) ABSTRACT

A method for growing an improved quality nitride thin film on a patterned substrate is disclosed, wherein the nitride film is grown at atmospheric pressure. A nitride template is disclosed, comprising a patterned substrate and a one or more nitride layer direct growth off of the patterned substrate, comprising no lateral epitaxial overgrowth regions and a substantially coalesced surface smooth enough for subsequent deposition of light emitting device quality nitride layers onto the surface. A light emitting diode comprising the nitride film is also disclosed.

### CROSS-REFERENCE TO RELATED APPLICATIONS

This application claims the benefit under 35 U.S.C. Section 119(e) of co-pending and commonly-assigned U.S. Provisional Patent Application Ser. No. 60/911,323 filed on Apr. 12, 2007, by Michael Iza, Steven P. DenBaars, and Shuji Nakamura, entitled “METHOD FOR DEPOSITION OF (Al,In,Ga,B)N” attorneys' docket number 30794.219-US-P1 (2007-338-1), which application is incorporated by reference herein.

### BACKGROUND OF THE INVENTION

1. Field of the Invention

This invention relates to a method for growing improved quality nitride films on patterned substrates by growing the nitride film at atmospheric pressure.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

The usefulness of gallium nitride (GaN) and its ternary and quaternary compounds, incorporating aluminum and indium (AlGaN, InGaN, AlInGaN), has been well established for fabrication of visible and ultraviolet optoelectronic devices and high-power electronic devices. These devices are typically grown epitaxially using growth techniques including molecular beam epitaxy (MBE), metalorganic chemical vapor deposition (MOCVD), and hydride vapor phase epitaxy (HVPE).

Nitride based optoelectronic devices began their quick ascent into commercialization with the advent of the use of a thin nucleation layer prior to the deposition of high quality GaN. This technique is employed due to the lack of a native substrate available for GaN growth. Later techniques, such as the development of p-type GaN by magnesium doping followed by high temperature anneal, also proved vital. However, the development of using InGaN as the active layer for short wavelength devices allowed nitride based Light Emitting Diodes (LEDs) and laser diodes (LDs) to overtake many other research ventures, and has now become the dominant material system used for visible light semiconductor applications.

The external quantum efficiency or total efficiency (η_{L}) of LEDs can be defined by the following equation:

η_{L}=ηᵢₙₜηᵢₙⱼηₑₓₜ

where the extraction efficiency, ηₙₑₓₜ, is defined as the amount of photons extracted, the injection efficiency, ηᵢₙₜ, is defined as the amount of carriers injected into the active region of the device, and the internal quantum efficiency, ηᵢₙₜ, is defined as the amount of photons generated in the active region of the device. The internal quantum efficiency of a device can be maximized by reducing the number of non-radiative centers, such as defects and impurities. The internal quantum and injection efficiency of blue nitride based LEDs have already been improved to a high level by optimizing the deposition conditions of the device layers. Therefore, further improvement in external efficiency of a device would require improvement in the extraction efficiency.

The extraction efficiency of nitride based devices grown on sapphire is hampered by the difference in the refractive index of nitride films and sapphire. This refractive difference in turn causes internal reflections which can “trap” the light generated in the active region. Therefore, most of the light that is generated propagates through the nitride film and cannot be used as useful light.

One approach to improve light extraction from nitride devices is to use a patterned substrate on which the device is subsequently grown. A patterned substrate is defined as any substrate which has been processed to produce surface features which include, but are not limited to, stripes, semicircles, pyramids, mesas of different shapes, etc. The pattern on the substrate aids in extracting the light emission from the active region of the device by the suppression of light interference. Early work of growth on patterned sapphire wafers, by Tadatomo et al., was initially employed to try to reduce the dislocation density of the nitride film by growing on patterned groves or stripes along different crystal growth directions [1].

This was done in order to avoid a two step growth procedure commonly referred to as Lateral Epitaxial Overgrowth (LEO), which uses a patterned SiO₂ stripe deposited atop an as grown nitride film in order to reduce the dislocation density of the nitride film grown atop the stripes. The LEO process is cumbersome due to the fact that the wafer must be removed from the reactor in order to deposit the SiO₂ stripes and then reintroduced into the reactor for regrowth of nitride films atop the patterned nitride film. Thus, the advantage of growing on a patterned substrate is that the growth can be performed in one deposition step compared to that of the LEO process.

Further improvements of LED devices grown on patterned substrates showed enhanced light extraction by use of various types of pattern designs [2]. These devices exhibited increased output powers and luminous efficiency compared to LED devices grown on non-patterned substrates. However, in order to maximize the use of a patterned substrate, it is necessary institute a robust growth technique which addresses the key problems associated with deposition of nitrides on a patterned substrate. These problems include, but are not limited to; non-coalesced and pitted films, rough film surface, and poor process reproducibility. The present invention addresses these issues by the use of a nitride film grown at atmospheric pressure. The current technology used in growth of nitrides employs the use of a nitride layer grown at reactor pressures less than or equal to 100 torr. This pressure range is employed in order to enhance the surface mobility of the depositing species and thereby enhance the lateral growth of the nitride film. However, this technique often results in the formation of pits and voids in the resulting nitride film, due to poor film coalescence and reproducibility [1,3].

The present invention distinguishes itself from above mentioned methods by the use of a nitride film grown at atmospheric pressure on a patterned substrate, in order to improve the surface and film quality of the nitride film. This improved film can further be used as a template for further device growth. As a result, there is a need for improved methods for the growth of a nitride film grown at atmospheric pressure, wherein the film exhibits a pit free and smooth surface onto which a nitride device can be subsequently deposited. The present invention satisfies this need.

### BRIEF DESCRIPTION OF THE DRAWINGS

Referring now to the drawings in which like reference numbers represent corresponding parts throughout:

FIG. 1 is a flowchart that illustrates the steps for the growth of nitride films deposited at atmospheric pressure on patterned substrates, according to the preferred embodiment of the present invention.

FIGS. 2(a) and 2(b) are photographs of 5 μm thick GaN film grown on a patterned sapphire substrate (PSS), wherein, for the sample in FIG. 2(a), the first 2.5 μm thickness of the GaN film was grown at atmospheric pressure, and the latter 2.5 μm thickness of the GaN film was grown at 76 torr, while, for the sample shown in FIG. 2(b), the entire 5 μm thickness of the GaN film was grown at atmospheric pressure.

FIGS. 3(a) and 3(b) are 5 μm×5 μm area Atomic Force Microscopy (AFM) images, wherein FIG. 3(a) shows the image for the sample grown on a patterned substrate in FIG. 2(b), and FIG. 3(b) shows 5 μm thick GaN grown on a non-patterned sapphire substrate.

FIG. 4 is a cross sectional schematic of a device according to the present invention.

### SUMMARY OF THE INVENTION

The present invention describes a method for growing an improved quality nitride film comprising of a nitride film grown at atmospheric pressure on a patterned substrate. The nitride film may be deposited at a pressure greater than 100 torr on a patterned substrate. The patterned substrate may consist of any pattern shape or design. The method may further comprise of any device or structure grown atop the nitride film grown at atmospheric pressure. For example, the present invention describes a method for growing a light emitting diode (LED) structure with improved light extraction efficiency, improved crystal quality, and with a nitride film, comprising growing the nitride film on a patterned substrate with a reactor pressure greater than 300 torr, or a reactor temperature greater than 1 atmosphere.

The nitride film grown at atmospheric pressure may comprise multiple layers having varying or graded compositions, a heterostructure comprising layers of dissimilar (Al,Ga,In,B)N composition, or one or more layers of dissimilar (Al,Ga,In,B)N composition. The nitride film grown at atmospheric pressure may be grown using deposition methods comprising hydride vapor phase epitaxy (HVPE), metalorganic chemical vapor deposition (MOCVD) or molecular beam epitaxy (MBE). The nitride film may be doped, for example, with elements such as Fe, Si, and Mg.

The method may further comprise the nitride film grown at atmospheric pressure grown in any crystallographic nitride direction, such as on a conventional c-plane oriented nitride semiconductor crystal or on a nonpolar plane such as a-plane or m-plane, or on any semipolar plane.

The present invention also discloses a film having enhanced properties using the method, and a device fabricated using the method.

The present invention further discloses a nitride template on a patterned substrate, comprising a patterned substrate and a one or more nitride layer direct growth off of the patterned substrate, comprising no lateral epitaxial overgrowth regions and a substantially coalesced surface smooth enough for subsequent deposition of light emitting device quality nitride layers onto the surface.

The nitride layer direct growth may have a crystal quality and surface roughness comparable to a crystal quality and surface roughness of a nitride lateral epitaxial overgrowth. The nitride layer direct growth may be a film thin enough to act as a nucleation layer or buffer layer. The nitride layer direct growth may have a single growth direction. The nitride layer direct growth may be without microscopic or larger pits, have no pits detrimental to a device's performance or have a crystal quality comparable to a crystal quality of a nitride direct growth off a non-patterned substrate. The nitride layer direct growth may be at a reactor pressure above 100 torr.

The nitride direct growth may be a substrate for an optoelectronic light emitting device. A commercial batch of templates may be fabricated, wherein each template has substantially identical crystal quality.

The present invention further discloses a light emitting diode (LED) structure, comprising a patterned substrate for extracting light emission from an active region of the LED by the suppression of light interference and a one or more nitride layer direct growth off of the patterned substrate, wherein the nitride layer direct growth comprises no lateral epitaxial overgrowth regions, a p-type layer on an-type layer or the n-type layer on the p-type layer, and each nitride layer has light emitting device crystal quality and a surface smooth enough for remaining nitride layers to be grown on top. The LED structure may be a device wafer.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention describes a method for growing improved quality nitride films on patterned substrates via MOCVD. Growth of nitride layers on patterned substrates deposited at atmospheric pressure offers a means of improving film properties in III-nitride structures. The terms “Group III nitrides,” “III-nitrides” or just “nitrides” refer to any alloy composition of the (Ga,Al,In,B)N semiconductors having the formula GaₙAlₓIn_{y}B_{z}N where:

0≦n≦1, 0≦x≦1, 0≦y≦1, 0≦z≦1, and n+x+y+z=1.

Current nitride films grown on patterned substrates comprise of a film grown at pressures less than or equal to 100 torr. These low pressure (LP) grown nitride films on patterned substrates show a drastic degradation in film coalescence, surface pits, and poor process reproducibility. Growing nitride films at atmospheric pressure on patterned substrates provides a means of enhancing (Ga,Al,In,B)N film quality, by greatly reducing surface pits and improving film coalescence and process reproducibility. The present invention provides a means of enhancing (Ga,Al,In,B)N films grown on patterned substrates.

Technical Description

The films of the present invention were grown using a commercially available MOCVD system. General growth parameters for nitride layers on patterned substrates deposited at atmospheric pressure comprise a pressure greater than 100 torr and a temperatures greater than 500° C. The epitaxial relationships and conditions should hold true regardless of the type of reactor used. However, the reactor conditions for growing nitride layers on patterned substrates deposited at atmospheric pressure will vary according to individual reactors and growth methods (HVPE, MOCVD, and MBE, for example).

Using this method, the nitride films show an improvement in film quality by a reduction in the number of surface pits and a significant enhancement in film coalescence. Improvement of the surface quality of the nitride film allows for subsequent growths on the film to occur without degradation to device performance or characteristics.

The method for growing a nitride film according the present invention generally comprises the following steps:

(1) Loading the substrate into an MOCVD reactor.

(2) Turning on a heater for the reactor and increasing the temperature in the reactor to a set point temperature, wherein nitrogen and/or hydrogen and/or ammonia flow over the substrate at atmospheric pressure.

(3) After a period of time, decreasing the set point temperature and introducing trimethylgallium (TMGa) and ammonia into the reactor to initiate growth of the GaN nucleation or buffer layer.

(4) After the GaN nucleation layer reaches a desired thickness, shutting off the flow of TMGa and increasing the reactor temperature to a set point.

(5) After the reactor set point temperature is achieved, turning on the flow of TMGa for the growth of unintentionally doped GaN.

(6) After the GaN film reaches the desired thickness, increasing the temperature and the TMGa flow.

(7) After the desired GaN thickness is achieved, turning off the TMGa flow while continuing to flow ammonia to preserve the GaN film.

The present invention is intended to cover a device fabricated using these steps.

Process Steps

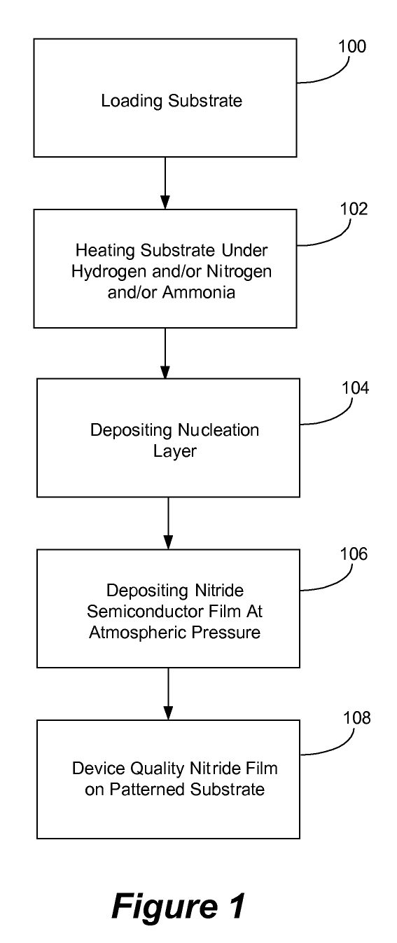

FIG. 1 is a flowchart that illustrates the steps for the growth of nitride films deposited at atmospheric pressure on patterned substrates, according to the preferred embodiment of the present invention.

Block 100 represents the step of loading a substrate into an MOCVD reactor, wherein the substrate may be a patterned sapphire (0001) substrate.

Block 102 represents the step of heating the substrate under hydrogen and/or nitrogen and/or ammonia flow. During this step, the reactor's heater is turned on and ramped to a set point temperature of 1100° C. Generally, nitrogen and/or hydrogen and/or ammonia flow over the substrate at atmospheric pressure.

Block 104 represents the step of depositing a nucleation layer on the substrate. During this step, twenty minutes after ramping to the set point temperature of Block 102, the reactor's set point temperature is decreased to 570° C. and 3 sccm of TMGa is introduced into the reactor to initiate the GaN nucleation or buffer layer growth. After 100 seconds, the GaN nucleation or buffer layer reaches the desired thickness. At this point, the TMGa flow is shut off and the reactor's temperature is increased to 1205° C.

Block 106 represents the step of depositing nitride semiconductor film at atmospheric pressure on the nucleation layer. During this step, once the set point temperature of block 104 is reached (e.g., 1205° C.), 7 sccm of TMGa may be introduced into the reactor to initiate the GaN growth for 120 minutes. Once the desired GaN thickness is achieved, 13 sccm of TMGa is introduced into the reactor for up to 15 minutes, and the reactor set temperature is increased to 1235° C. Once a desired GaN film grown at atmospheric pressure is achieved, the reactor is cooled down while flowing ammonia to preserve the GaN film.

Block 108 represents the end result of the method, comprising a device quality nitride film grown at atmospheric pressure on a patterned substrate.

Advantages and Improvements

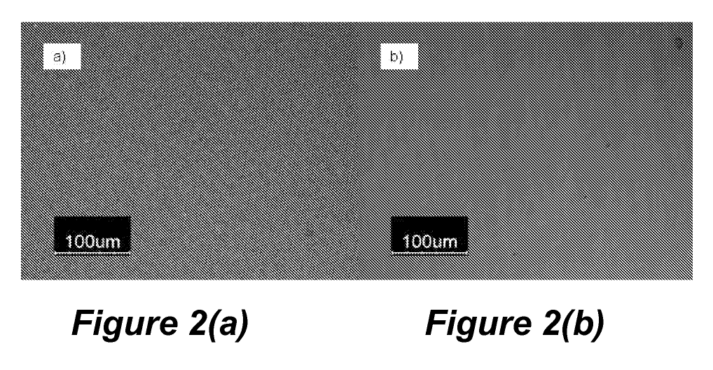

FIGS. 2(a) and 2(b) show optical micrographs of 5 μm thick GaN films grown on a patterned sapphire substrate (PSS). For the sample shown in FIG. 2(a), the first 2.5 μm thickness of the GaN film was grown at atmospheric pressure, and the latter 2.5 μm thickness of the GaN film was grown at 76 torr. For the sample shown in FIG. 2(b), the entire 5 μm thickness of the GaN film was grown at atmospheric pressure. It is clear from the micrographs that the film grown entirely at atmospheric pressure exhibits enhanced film coalescence. On the other hand, the film grown at a pressure of 76 torr shows a largely uncoalesced film with some small spots of coalescence.

Most growth on patterned substrates employ nitride films grown at LP [3,4]. However it is clear from the present study that the use of a nitride film grown at atmospheric pressure is far superior to films grown at LP.

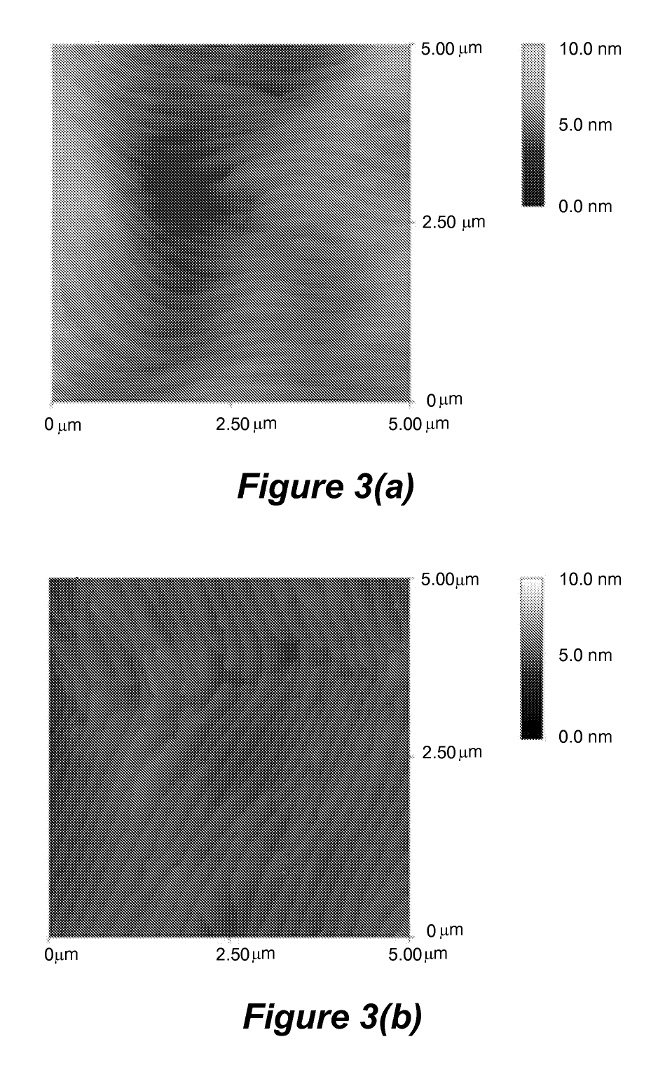

An AFM image of a 5 μm×5 μm area of the sample in FIG. 2(b) is shown in FIG. 3(a). This image demonstrates a film with a Root Mean Square (RMS) surface roughness of 0.94 nm. Although this value is slightly higher than that of state of the art GaN on non-patterned substrates, which have typical values of 0.4 nm, it is well within the range usable for subsequent device growth without the occurrence of negative effects. It is also important to note that these films show no macroscopic or microscopic surface pits which can be detrimental to device performance.

Possible Modifications and Variations

The method described above is just one embodiment of the invention. The most general embodiment of the present invention involves growth of one or more nitride layers on a patterned substrate at a pressure greater than 100 torr.

Template or Substrate Embodiment of the Present Invention

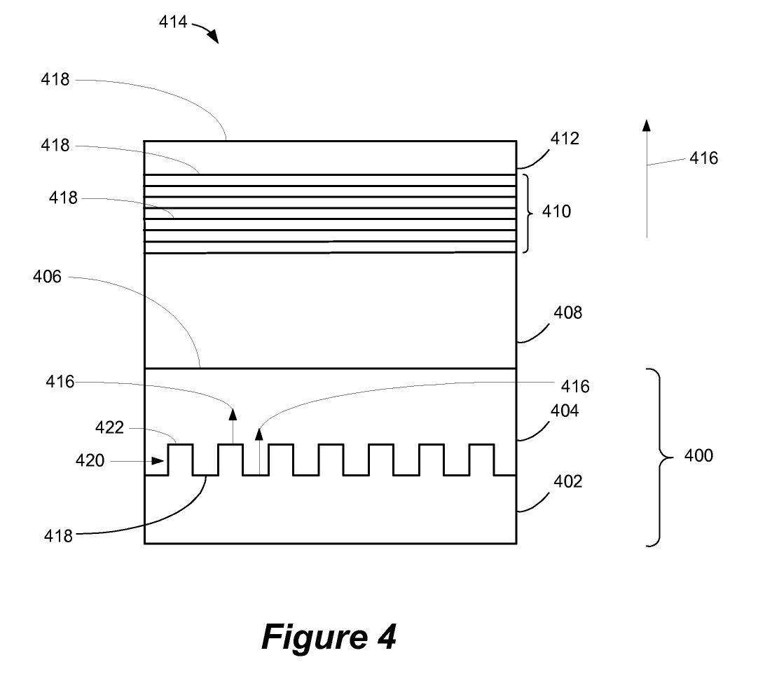

FIG. 1 and FIG. 4 show how the present invention discloses a nitride template or substrate 108, 400 (e.g., epitaxial or crystal layers), comprising a patterned substrate 100, 402 and a one or more nitride layer direct growth 106, 404 (i.e. a direct growth of one or more nitride layers) off of the patterned substrate 100, 402, wherein the direct growth 106, 404 comprises no lateral epitaxial overgrowth regions, a substantially coalesced surface (FIG. 2(b), 406) smooth enough (FIG. 3(a), 406) for subsequent deposition of device quality nitride layers 408, 410, 412 onto the surface 406 (e.g., sufficient crystal quality for a light emitting device). The nitride growth 404 may be without microscopic or larger pits and/or have no pits detrimental to the device's 414 performance (either within the nitride layer growth 106, 404 or on the surface 406 of the growth 404). The surface 406 and the direct growth of one or more nitride layers 404 have a crystal quality comparable to a crystal quality of a direct growth of one or more nitride layers grown on a non-patterned substrate, which have a typical (RMS) surface roughness of <2 nm for a 5 μm×5 μm area as measured by AFM and do not contain any macroscopic or microscopic pits.

The one or more nitride layer direct growth 106, 404 may have a single growth direction 416, for example, and growth from the bottom 418 of the patterned surface feature 420 of the patterned substrate 402 may have the same direction 416 as growth from the top 422 of the patterned surface feature 420, as opposed to lateral epitaxial overgrowth which has at least two growth directions—vertical and lateral. However, the nitride layer direct growth 106, 404 may have a crystal quality and surface roughness comparable to a crystal quality and surface roughness of a nitride lateral epitaxial overgrowth. The nitride film 106, 404 may be grown in any crystallographic nitride direction 416 such as on a conventional c-plane oriented nitride semiconductor crystal or on a nonpolar plane such as a-plane or m-plane, or any semipolar plane.

The nitride layer direct growth 106, 404 may be a nitride film formed by one or more nitride layers. The film 404, 106 may be thick, or may be thin enough to act as a nucleation layer or buffer layer for subsequent nitride growth 408, 410, 412, or merely thin enough for the film 106 to substantially coalesce. Typical film thicknesses would be between 0.2 μm to 10 μm, although this present invention is not limited to these typical thickness ranges.

The nitride template 108, 400, or the nitride layers 404, may be a substrate for subsequent growth, for example, growth of an optoelectronic light emitting device structure (such as an LED layers 408-412), or transistor, on the surface 406 of the template 400 or direct growth 404. The subsequent growth 408-412 may be by hydride vapor phase epitaxy (HVPE), metalorganic chemical vapor deposition (MOCVD), and/or molecular beam epitaxy (MBE).

In a commercial context, it is desirable to reproducibly fabricate a large number, such as hundreds, of substrates 400 or wafers each having substantially identical crystal quality to satisfy commercial production tolerances for mass production. Each wafer or substrate 400 in the batch may, for example, originate from substantially identical growth reactors operating under substantially identical growth conditions or in a substantially identical manner. The method of the present invention allows a plurality of templates 108, 400 to be grown reproducibly, wherein each nitride film 404, 106 may be grown on a separate patterned substrate 402, 100 and have substantially similar crystal quality. This was not possible prior to the present invention.

Device Embodiment of the Present Invention

FIG. 4 shows how the present invention also discloses a device structure 414, such as an LED, comprising a patterned substrate 402 for extracting light emission from an active region 410 of the LED 414 by the suppression of light interference, a one or more nitride layer direct growth 106, 404, 408, 410, 412 off of the patterned substrate 402, wherein the nitride layer direct growth 106, 404 may comprise no lateral epitaxial overgrowth regions, a p-type layer 412 on an n-type layer 408 (or the n-type layer on the p-type layer, not shown), an active layer 410 between the p-type layer 412 and the n-type layer 408, and other layers known in the art to be used to fabricate an LED or other device. Each nitride layer 404, 408, 410, 412 may have light emitting device crystal quality and a growth surface 406, 418 smooth enough for remaining nitride layers to be grown on top. The LED structure 414 may be a wafer, from which LED devices may be separated.

Thus, the nitride film 106 may comprise multiple layers having varying or graded compositions. The nitride film 106 may contain one or more layers of dissimilar (Al,Ga,In,B)N composition, or the nitride film 106 may be a heterostructure containing layers of dissimilar (Al,Ga,In,B)N composition. The nitride film 106 may be doped, with elements such as Fe, Si, and Mg, for example. In this way the nitride film may comprise one or more device layers for fabrication of a light emitting device or transistor.

Thus, the present invention discloses a method for growing a light emitting diode (LED) structure 414 with improved light extraction efficiency and improved crystal quality with a nitride film 106, comprising growing the nitride film 106 on a patterned substrate 100 with a reactor pressure greater than 300 torr, or even at a reactor temperature greater than 1 atmosphere. The patterned substrate 100, 402 may be any substrate suitable for nitride growth, including but not limited to, substrates that do not contain lateral epitaxial overgrowths.

### REFERENCES

The following references are incorporated by reference herein:
[1] K. Tadatomo, H. Okagawa, Y. Ohuchi, T. Tsunekawa, T. Joyuichi, Y. Imada, M. Kato, H. Kudo, and T. Taguchi, Phys. Stat. Sol. (a) 188, No. 1, pp. 121-125 (2001).
[2] Motokazu Yamada, Tomotsugu Mitani, Yukio Narukawa, Shuji Shioji, Isamu Niki, Shinya Sonobe, Kouichiro Deguchi, Masahiko Sano and Takashi Mukai, Jpn. J. Appl. Phys. Vol. 41, Part 2, No. 12B, pp. L 1431-L 1433, 15 Dec. 2002.
[3] Woei-Kai Wang, Dong-Sing Wuu, Shu-Hei Lin, Pin Han, Ray-Hua Horng, Ta-Cheng Hsu, Donald Tai-Chan Huo, Ming-Jiunn Jou, Yuan-Hsin Yu, and Aikey Lin, IEEE Journal of Quantum Electronics, Vol. 41, No. 11, November 2005.
[4] Chang-Soo Kim, Ji-Hyun Moon, Sang-Jun Lee, Sam-Kyu Noh, Je Won Kim, Kyuhan Lee, Yong Dae Choi, and Jay P. Song, Mater. Res. Soc. Symp. Proc. Vol. 864 © 2005 Materials Research Society.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A method for growing a light emitting diode (LED) structure with improved light extraction efficiency and improved crystal quality with a nitride film, comprising:
growing the nitride film on a patterned substrate with a reactor pressure greater than 300 torr.

2. The method of claim 1, wherein the nitride film is grown at a reactor pressure of 1 atmosphere.

3. The method of claim 1, wherein the nitride film comprises multiple layers having varying or graded compositions.

4. The method of claim 1, wherein the nitride film comprises a heterostructure containing layers of dissimilar (Al,Ga,In,B)N composition.

5. The method of claim 1, wherein the nitride film is doped with elements Iron (Fe), Silicon (Si), or Magnesium (Mg).

6. The method of claim 1, wherein the nitride film contains one or more layers of dissimilar (Al,Ga,In,B)N composition.

7. The method of claim 1, wherein the nitride film is used as a substrate for subsequent growth, such as that by hydride vapor phase epitaxy (HVPE), metalorganic chemical vapor deposition (MOCVD), or molecular beam epitaxy (MBE).

8. The method of claim 1, wherein the nitride film is grown in any crystallographic nitride direction such as on a conventional c-plane oriented nitride semiconductor crystal, or on a nonpolar plane, or any semipolar plane.

9. A device fabricated using the method of claim 1.

10. A nitride template on a patterned substrate, comprising:
(a) a patterned substrate; and
(b) a nitride layer direct growth off of the patterned substrate, comprising:
no lateral epitaxial overgrowth regions; and
a substantially coalesced surface smooth enough for subsequent deposition of device quality nitride layers onto the surface.

11. The nitride template of claim 10, wherein the nitride layer direct growth has a crystal quality and surface roughness comparable to a crystal quality and surface roughness of a nitride lateral epitaxial overgrowth.

12. The nitride template of claim 10, wherein the nitride layer direct growth is a film thin enough to act as a nucleation layer or buffer layer.

13. The nitride direct growth of claim 10, wherein the nitride layer direct growth has a single growth direction.

14. The nitride direct growth of claim 10, wherein the nitride layer direct growth is without microscopic or larger pits.

15. The nitride direct growth of claim 10, wherein the nitride layer direct growth has no pits detrimental to the device's performance.

16. The nitride direct growth of claim 10, wherein the nitride layer direct growth has a crystal quality comparable to a crystal quality of a nitride direct growth off a non-patterned substrate.

17. The nitride direct growth of claim 10, wherein the nitride layer direct growth is at a reactor pressure above 300 torr.

18. The nitride direct growth of claim 10, wherein the nitride layer direct growth provides a substrate for an optoelectronic device.

19. A light emitting diode (LED) structure, comprising:
(a) a patterned substrate for extracting light emission from an active region of the LED by a suppression of light interference; and
(b) a nitride layer direct growth off of the patterned substrate, wherein the nitride layer direct growth comprises:
(1) no lateral epitaxial overgrowth regions;
(2) a p-type layer on an-type layer or the n-type layer on the p-type layer; and
(3) each nitride layer has light emitting device crystal quality and a surface smooth enough for remaining nitride layers to be grown on top.
